(19) United States
(12) Patent Application Publication
(10) Pub. No.: US 2026/0196437 A1
(43) Pub. Date: Jul. 9, 2026

(54) ION GENERATION APPARATUS

(71) Applicant: Fidelity semiconductor CORPORATION, Hsinchu City (TW)

(72) Inventors: CHIH MING CHEN, HSINCHU CITY (TW); KUO CHAN HUANG, HSINCHU CITY (TW)

(21) Appl. No.: 19/181,357

(22) Filed: Apr. 17, 2025

(30) Foreign Application Priority Data
Jan. 3, 2025 (TW) 114100391

(51) Int. Cl. H01J 37/08; H01J 37/317

(52) U.S. Cl. CPC H01J 37/08; H01J 37/3171

(57) ABSTRACT

An ion generation device apparatus is provided, comprising: an arc chamber housing, forming an ion source arc chamber; a thermionic emitter, comprising a filament and a cathode positioned at an end of the ion source arc chamber; and a guide member, positioned around the cathode to form a guide channel, wherein a top end surface of the guide member protrudes higher than an upper surface of the cathode, wherein at least two gas inlets positioned on the ion source arc chamber are correspondingly and symmetrically positioned on two sides of a central extension line of the cathode, to more evenly provide a source gas to the ion source arc chamber. In addition, electrons are enabled to move as far as possible to the gas inlets by using the guide member, thereby increasing an opportunity that the electrons react with the gas.

### CROSS-REFERENCE TO RELATED APPLICATION

This application claims the benefit of Taiwan Patent Application No. 114100391, filed on January 03, 2025, which is hereby incorporated by reference for all purposes as if fully set forth herein.

### BACKGROUND

### Technical Field

The present invention relates to the field of semiconductor device manufacturing technologies, and specifically, to an ion generation apparatus applied to an ion implanter to manufacture an ion source.

### Related Art

When a semiconductor device is to be manufactured, during ion implantation, a semiconductor is doped with impurities. An ion implantation system is often used to dope ions to semiconductor wafer from an ion beam, to produce n-type or p-type material doping during manufacturing of an integrated circuit. Such beam processing is often selectively implanted into a wafer by using impurities of a specified dopant material at a predetermined energy level and in a controlled concentration, to generate a semiconductor material during manufacturing of the integrated circuit. When used to dope the semiconductor wafer, the ion implantation system injects a selected ion species into the semiconductor wafer to generate a required extrinsic material. For example, implanting ions generated by a source material (such as antimony, arsenic, or phosphorus) generates an "n-type" extrinsic semiconductors, while a "p-type" extrinsic semiconductors is often generated from ions generated by a source material such as boron, gallium, or indium.

A typical ion implantation system includes an ion source, an ion extraction device apparatus, a mass analysis device apparatus, a beam delivery device apparatus, and a wafer processing device apparatus. The ion source produces ions of a required atomic or molecular doping species. The ions are extracted from a source by an extraction system (typically a group of electrodes), to form an ion beam. The group of electrodes supply energy and guide an ion flow from the source. The required ions are extracted separately from the ion beam in the mass analysis device apparatus, and the mass analysis device apparatus is typically a magnetic dipole that separates the required dopant species from associated impurity ion beams. The beam delivery device apparatus (typically a vacuum system including a series of focusing device apparatuses) delivers the ion beam to the wafer processing device apparatus. Finally, a semiconductor wafer is transferred into or removed from the wafer processing device apparatus by using a wafer processing system, and the wafer processing system may include one or more robot arms configured to place a to-be-processed wafer in front of the ion beam and remove a processed wafer from the ion implanter.

FIG. 1 is a schematic cross-sectional diagram of a known ion generation device apparatus. A structure of an existing ion generation device apparatus 10 of an ion source includes: an arc chamber housing 11, forming an ion source arc chamber 12; and a thermionic emitter, including a filament 21 and a cathode 22. The filament 21 and the cathode 22 are positioned at an end of the ion source arc chamber 12, and at least one gas inlet 13 used to provide a source gas is further positioned on the ion source arc chamber 12. A repeller 23 is further positioned at another end of the ion source arc chamber 12, so that the repeller 23 is positioned opposite to the cathode 22 and may have an equal potential or a relative floating potential. During implementation, two source magnets 30 are respectively outside the arc chamber housing 11 in a manner of being corresponding to the repeller 23 and the cathode 22. During implementation and application, the filament 21 is heated by a power supply to an emission temperature generated by thermal electrons, and electrons emitted from the filament 21 toward the cathode 22 are accelerated by a voltage difference between the filament 21 and the cathode 22, until the cathode 22 generates thermal electrons.

As shown in FIG. 2 and FIG. 3, the cathode 22 generates initial electrons 41 and the initial electrons 41 are attracted by an electric field (E_{Arc}). Starting an electron moving path is affected by a voltage of the arc chamber housing 11 and the source magnet 30, and electrons tend to move to a side wall of the arc chamber housing 11 near the cathode 22. In this case, only a few effective electrons 41 react with a gas 42 to form ions 43 and form plasma in the ion source arc chamber 12, and most ineffective electrons 41 are attracted to the side wall to form an arc current. Because of a design problem of the existing ion generation device apparatus 10, the electrons 41 tend to move to the side wall of the arc chamber housing 11 near the cathode 22, so that the efficiency of the effective electrons reacting with the gas to form the ions is not high. However, a unionized reactive gas molecule easily deposits in a wall of the ion source arc chamber 12 to generate a thin film generator. When depositing to a thickness, the thin film generator may come into contact with the cathode, and in a serious case, a short circuit may occur between the cathode 22 and the arc chamber housing 11. In this case, the ion generation device apparatus 10 needs to be removed for cleaning, and the cathode needs to be replaced, thereby greatly shortening a service life of the existing ion generation device apparatus 10.

### SUMMARY

An objective of the present invention is to provide an ion generation device apparatus, to increase the plasma ionization efficiency. Compared with the existing ion generation device apparatus, the ion generation efficiency can be increased by 40% to 100%, a thin film generator generated through deposition of a unionized gas in a chamber wall can be reduced, and in addition, a larger ion beam current can be obtained, to increase a generation rate of an ion source.

Another objective of the present invention is to provide an ion generation device apparatus, to increase the plasma ionization efficiency under a same ion beam current, reduce a heating current of a filament and a cathode, and save a reaction gas, so that energy consumption and manufacturing costs can be reduced, and a service life of the ion generation device apparatus can be prolonged.

To achieve the foregoing objectives, the present invention provides an ion generation device apparatus, comprising: an arc chamber housing, forming an ion source arc chamber; a thermionic emitter, comprising a filament and a cathode positioned at an end of the ion source arc chamber; and a guide member, around the cathode to form a guide channel, wherein a top end surface of the guide member protrudes higher than an upper surface of the cathode, wherein at least two gas inlets used to provide a gas are positioned on the ion source arc chamber, and the gas inlets are correspondingly and symmetrically positioned on two sides of a central extension line of the cathode, to more evenly provide a gas to the ion source arc chamber; and electrons are guided to the gas inlets by using the guide member, thereby improving the ionization efficiency of the gas.

Optionally, the top end surface of the guide member is higher than the upper surface of the cathode by 0.1 mm to 50 mm.

Optionally, a thickness of the guide member is in a range of 0.1 mm to 10 mm.

Optionally, the cathode and the guide member are jointly placed on a support plate; a gap between the guide member and the cathode is in a range of 0.1 mm to 10 mm; and a spacing in a range of 0.1 mm to 10 mm is set between the guide member and the arc chamber housing.

Optionally, at least one second gas inlet is correspondingly positioned on each side of the surfaces adjacent to the gas inlets located on the ion source arc chamber.

Compared with the related art, based on the ion generation device apparatus in the present invention, impact of an electric field on electrons in an ion source arc is changed due to setting of the guide member, so that an average action path of the electrons is increased, and a movement path of thermal electrons is controlled to pass through a position of a peak of gas molecules, to enable the electrons to more effectively react with the gas molecules, so that the overall ionization efficiency in the ion source arc chamber is increased. Compared with the existing ion generation device apparatus, based on the technology of this specification, the ion generation efficiency can be increased by 40% to 100%, a film generator generated through deposition of a unionized gas in a wall of the ion source arc chamber can be reduced, a larger ion beam current can be achieved, a heating current of the filament and the cathode can be reduced, and a reaction gas can be saved, thereby saving energy consumption and manufacturing costs, and increasing a service life of the ion generation device apparatus.

### BRIEF DESCRIPTION OF THE DRAWINGS

FIG. 1 is a schematic cross-sectional diagram of a known ion generation device apparatus.

FIG. 2 is a schematic diagram of a cathode generating electrons and the electrons being attracted by an electric field in FIG. 1.

FIG. 3 is a schematic diagram of an electron path in FIG. 2.

FIG. 4 is a schematic cross-sectional diagram of an ion generation device apparatus in this specification.

FIG. 5 is a schematic cross-sectional diagram of a cathode and a guide member in this specification.

FIG. 6 is a schematic diagram of configuration of a gas inlet in this specification.

FIG. 7 is a schematic diagram 1 of an electron path in FIG. 4.

FIG. 8 is a schematic diagram 2 of an electron path in FIG. 4.

### DETAILED DESCRIPTION

The following describes the various embodiments of the present invention in detail, and the drawings are used as examples. In addition to these detailed descriptions, the present invention may be widely implemented in other embodiments, and easy substitution, modification, and equivalent changes of any of the embodiments are included within the scope of the present invention, and are subject to the scope of the patent application. In the descriptions of the specification, many specific details are provided to enable readers to understand the present invention completely. However, the present invention may still be implemented with some or all specific details omitted. In addition, known steps or components are not described in detail to avoid unnecessary limitations on the present invention. The same or similar components in the drawings are represented by the same or similar symbols. In particular, the drawings are merely illustrative and do not represent the actual size or quantity of the components. Some details may not be fully drawn for simplicity of the drawings.

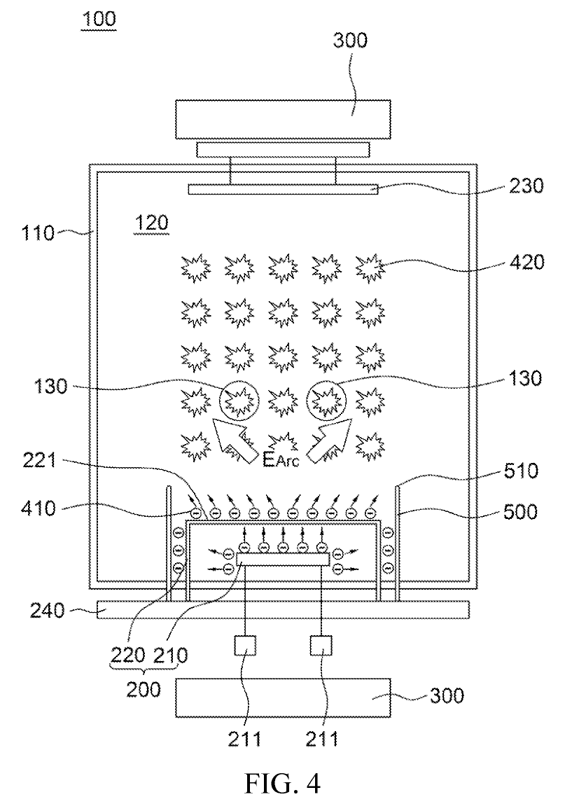

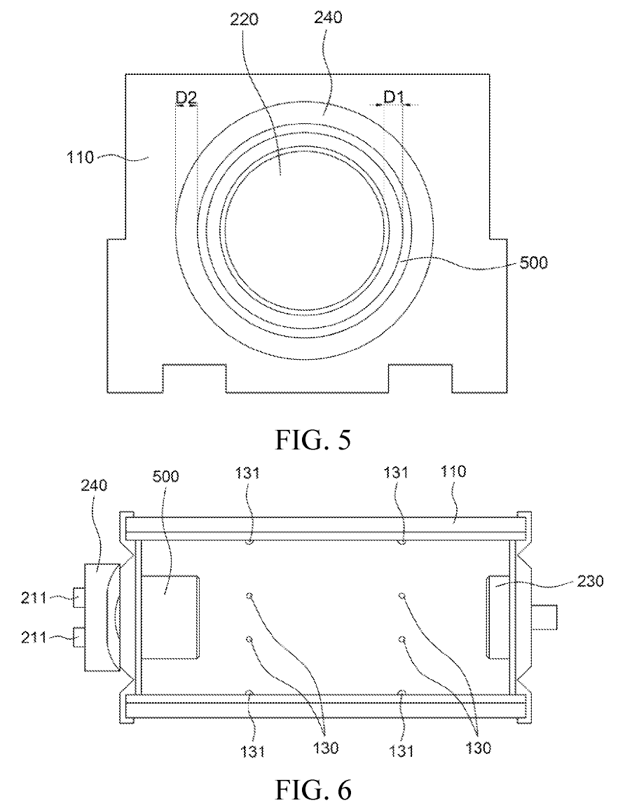

Refer to FIG. 4 to FIG. 6 first. During implementation and application, the ion generation device apparatus 100 of this specification includes: an arc chamber housing 110. An ion source arc chamber 120 is formed inside the arc chamber housing 110. A thermionic emitter 200 includes a filament 210 and a cathode 220. The cathode 220 is positioned at an end of the ion source arc chamber 120. The cathode 220 includes a hollow bottom, and the filament 210 is positioned in an area of the hollow bottom of the cathode 220 by using a filament holder 211. During implementation, the filament 210, the cathode 220, and the arc chamber housing 110 are not mutually connected and have their own external voltages. The filament 210 is heated by a power supply to an emission temperature generated by thermal electrons, and electrons emitted from the filament 210 toward the cathode 220 are accelerated by a voltage difference between the filament 210 and the cathode 220, until the cathode 220 generates thermal electrons.

The guide member 500 is placed around the cathode 220 to form a guide channel, and a top end surface 510 of the guide member 500 protrudes higher than an upper surface 221 of the cathode 220. The guide channel formed by the guide member 500 is used to guide a direction of a moving path used when electrons 410 thermally emitted by the cathode 220 are attracted by an electric field (E_{Arc}). At least two gas inlets 130 for supplying a gas 420 are positioned on the ion source arc chamber, and the gas inlets 130 are correspondingly and symmetrically positioned on two sides of a central extension line of the cathode 220, to more evenly provide the gas to the inside of the ion source arc chamber 120. The electrons 410 generated by the cathode 220 are enabled to move as far as possible to the inlets of the gas 420 by using the guide member 500, thereby increasing the ionization efficiency of the gas.

During implementation and application, the guide member 500 may be made of tungsten or graphite. The top end surface 510 of the guide member 500 is about 0.1 mm to 50 mm higher than the upper surface 221 of the cathode 220. A thickness of the guide member 500 is in a range of about 0.1 mm to 10 mm.

During implementation and application, the cathode 220 and the guide member 500 can be jointly placed on a support plate 240, and the support plate 240 may be a graphite support plate. A gap D1 between the guide member 500 and the cathode 220 is in a range of about 0.1 mm to 10 mm, to better form the guide channel. A spacing D2 in a range of about 0.1 mm to 10 mm is set between the guide member 500 and the arc chamber housing 110, to avoid a short circuit.

As disclosed in the known application technology, the ion source arc chamber 120 as an ion source has an opening at an end portion, and the cathode 220 is positioned at an end portion inside the ion source arc chamber 120. Electrons thermally emitted by the cathode 220 generates plasma in the ion source arc chamber 120. Finally, ions and/or other impurities generated in the ion source arc chamber 120 are discharged through an extraction aperture (not shown in the figure) of the ion source arc chamber 120 on a side of the arc chamber housing 110.

During implementation and application, a repeller 230 is further positioned in the ion source arc chamber 120 and coupled to the arc chamber housing 11. The repeller 230 is positioned opposite to the cathode 220. The repeller 230 and the cathode 220 have a same potential and apply a bias to another end of the ion source arc chamber 120, to repel high-energy electrons formed in the ion source arc chamber 120. During technical implementation of this specification, the repeller 230, the cathode 220, and the guide member 500 have a same potential, and can apply a bias by using the same potential or can be connected to an external potential respectively.

During implementation, two source magnets 300 are respectively disposed outside the arc chamber housing 110 in a manner of being corresponding to the repeller 230 and the cathode 220. In some other known embodiments, one or more source magnets 300 can be used to generate a magnetic field. The source magnets 300 can be used to apply a magnetic field to increase the efficiency of generating plasma in the ion source arc chamber 120. A direction of the magnetic field applied by the source magnets 300 corresponds to a length direction of the foregoing extraction aperture.

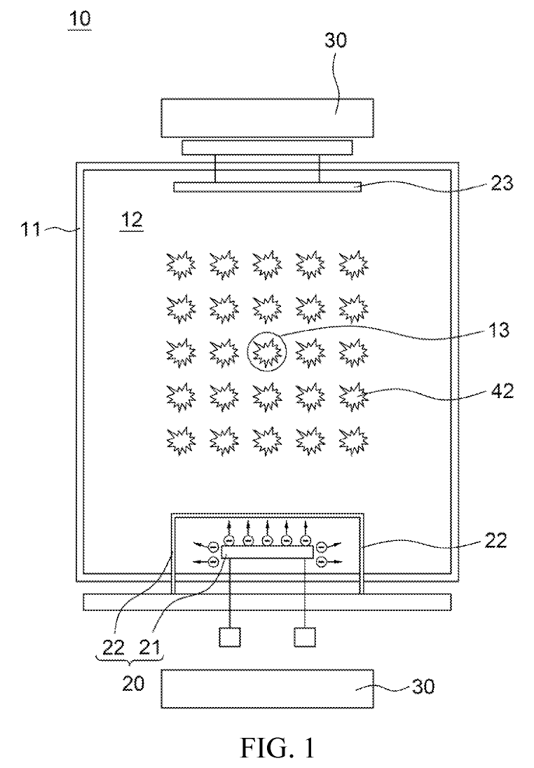

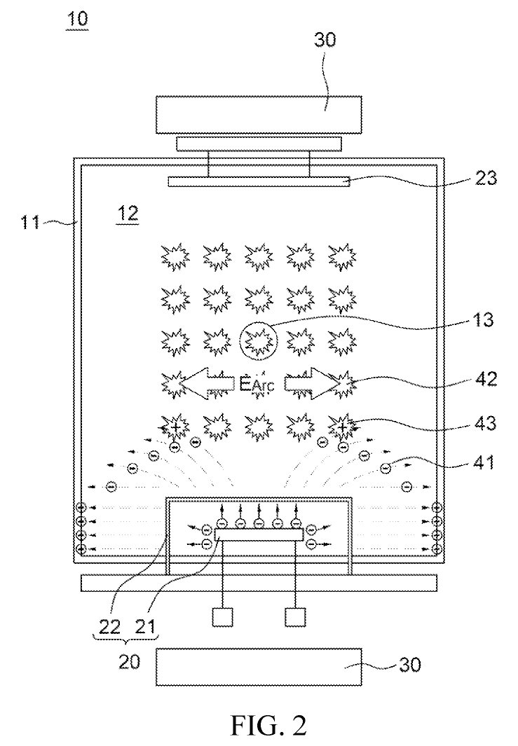

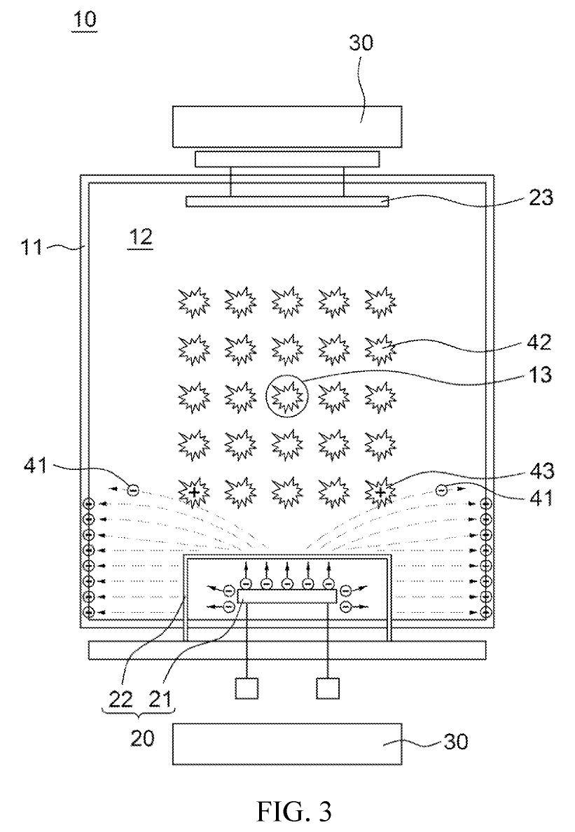

During implementation and application, different from the known ion source arc chamber 12 on which the gas inlet 13 is aligned with the central extension line of the cathode 22 (as shown in FIG. 1) (there may be two gas inlets 13 during implementation), no matter how many gas inlets 13 there are, the gas inlets are all aligned with the central extension line of the cathode 22.

However, in this specification, at least two gas inlets 130 are positioned on the ion source arc chamber 120. The gas inlets 130 are positioned between the central extension line of the cathode 220 and two sides of the arc chamber housing 110, and are symmetrical on the two sides along the central extension line of the cathode 220 (as shown in FIG. 6), so that a source gas can be provided more evenly to the inside of the ion source arc chamber 120. In some other embodiments, more than four gas inlets 130 can be used. However, the gas inlets 130 are symmetrically positioned on the two sides of the central extension line of the cathode 220.

During implementation and application, at least one second gas inlet 131 is correspondingly positioned on each of two sides of surfaces of the gas inlets 130 positioned on the ion source arc chamber 120. As shown in FIG. 6, four second gas inlets 131 corresponding to each other pairwise are positioned on the sides, and a source gas can be more evenly provided to the inside of the ion source arc chamber 120 through the second gas inlets 131.

Specifically, the gas inlets 130 (including the second gas inlets 131) are connected to a gas manifold, and a source gas for ionization is fed into the ion source arc chamber 120 through the gas manifold. The gas manifold may provide the source gas in a form of gas compounds or vapors, so that the gas is ionized in the ion source arc chamber 120.

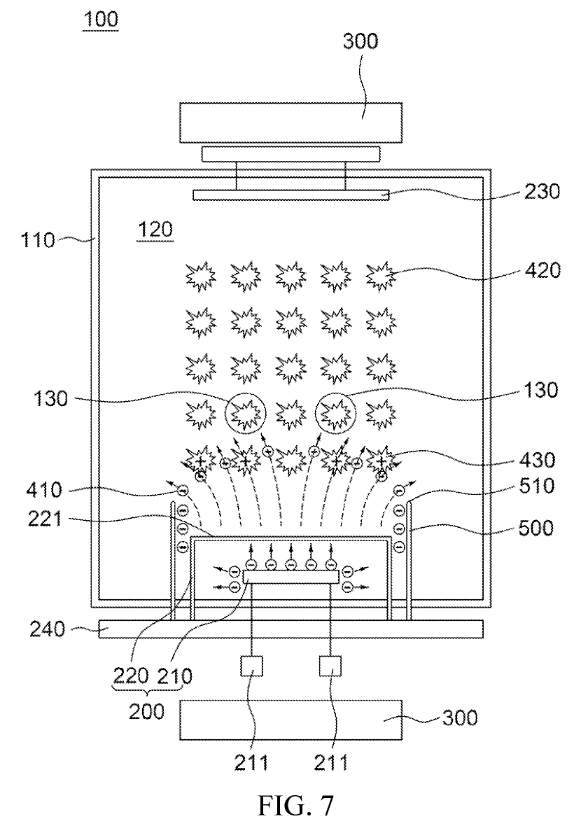

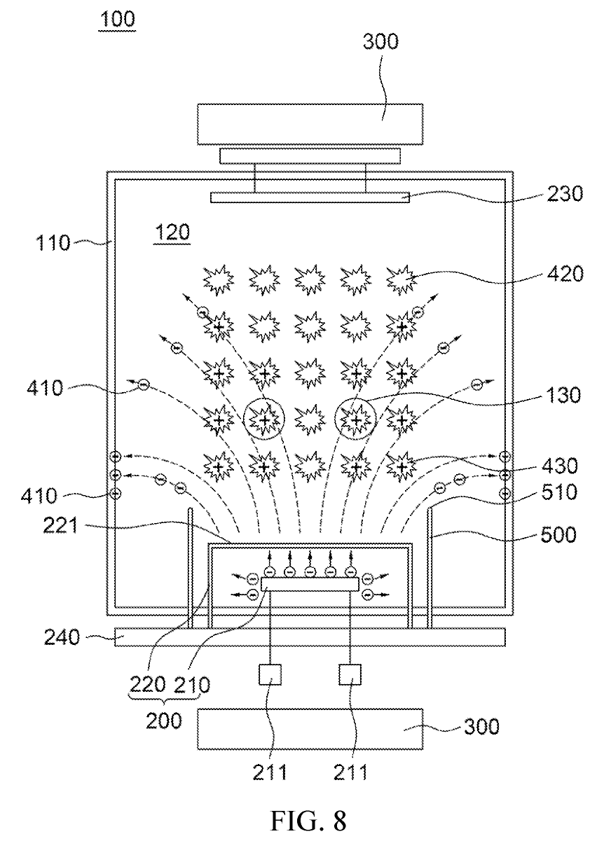

FIG. 7 and FIG. 8 are schematic diagrams of electron paths. The electrons 410 thermally generated by the cathode 220 are attracted by the electric field (E_{Arc}) (as shown in FIG. 4), and the top end surface 510 of the guide member 500 protrudes higher than the upper surface 221 of the cathode 220. In this case, the guide member 500 plays a role similar to a role of a conduit channel, so that the electrons 410 generated by the cathode 220 are diffused outward from a top end of the guide member 500. The gas 420 is evenly provided to the inside of the ion source arc chamber 120 through the gas inlets 130 (the second gas inlet 131). Based on the technology of this specification, impact of the electric field (E_{Arc}) on the electrons 410 generated by the cathode 220 in the ion source arc chamber 120 is changed through setting of the guide member 500, so that an average upward action path of the electrons 410 is increased, and the action path of the electrons 410 can be controlled to pass through a position of a peak of molecules of the gas 420-the gas inlet 130 (as shown in FIG. 7 and FIG. 8). Under same energy consumption and a same gas supply, more effective electrons 410 react with the gas 420 to form ions 430, so that the overall ionization efficiency in an ion source arc is increased, and the efficiency of generating ions 430 can be increased by 40% to 100%. In contrast, when the efficiency of generating the ions 430 is increased, a quantity of the gases 420 used may also be reduced.

During technical implementation and application, this specification can be applied to the known ion generation device apparatus 100. Basically, as long as a direction of the electrons thermally emitted by the cathode 220 is guided through the setting of the guide member 500, an opportunity that the electrons react with the gas is increased. Compared with the existing known devices, based on the technology of this specification, a quantity of arc currents formed by ineffective electrons attracted to the side wall is reduced, and the thin film generators generated through deposition of the unionized gas is reduced.

Compared with the related art, the ion generation device apparatus in the present invention has an effect of changing impact of the electric field on the electrons in the ion source arc chamber due to the setting of the guide member, so that an average action path of the electrons is increased, and the action path of the electrons is controlled to pass through a position of a peak of gas molecules, to enable the electrons more effectively react with the gas molecules, so that the overall ionization efficiency in the ion source arc chamber is increased. The thin film generator generated through the deposition of the unionized gas in the wall of the chamber can be reduced, a larger ion beam current can be achieved, a heating current of the filament and the cathode can be reduced, and the reaction gas can be saved, thereby saving energy consumption and manufacturing costs, and increasing the service life of the ion generation device apparatus.

The above disclosed implementation forms only exemplarily describe the principles, features, and effects of the present invention, and are not intended to limit the implementation scope of the present invention. Any person skilled in the art may modify and alter the above implementation forms without departing from the spirit and scope of the present invention. Any equivalent changes and modifications made using the contents disclosed by the present invention shall still fall within the scope of the following patent application.

What is claimed is:

1. An ion generation device apparatus, comprising:
an arc chamber housing, forming an ion source arc chamber;
a thermionic emitter, comprising a filament and a cathode positioned at an end of the ion source arc chamber; and
a guide member, annularly placed around the cathode to form a guide channel, wherein a top end surface of the guide member protrudes higher than an upper surface of the cathode,
wherein at least two gas inlets used to provide a gas are positioned on the ion source arc chamber, and the gas inlets are correspondingly and symmetrically positioned on two sides of a central extension line of the cathode, to more evenly provide a gas to the ion source arc chamber; and electrons are enabled to move as far as possible to the gas inlets by using the guide member, thereby increasing the ionization efficiency of the gas.

2. The ion generation device apparatus according to claim 1, wherein the top end surface of the guide member is higher than the upper surface of the cathode by 0.1 mm to 50 mm.

3. The ion generation device apparatus according to claim 1, wherein a thickness of the guide member is in a range of 0.1 mm to 10 mm.

4. The ion generation device apparatus according to claim 1, wherein the cathode and the guide member are jointly placed on a support plate.

5. The ion generation device apparatus according to claim 4, wherein a gap between the guide member and the cathode is in a range of 0.1 mm to 10 mm.

6. The ion generation device apparatus according to claim 4, wherein a spacing in a range of 0.1 mm to 10 mm is set between the guide member and the arc chamber housing.

7. The ion generation device apparatus according to claim 1, wherein at least one second gas inlet is correspondingly positioned on each of two sides of surfaces of the gas inlets positioned on the ion source arc chamber.
